(19) United States
(12) Patent Application Publication
(10) Pub. No.: US 2004/0265748 A1
(43) Pub. Date: Dec. 30, 2004

(54) Pattern transfer of an extreme ultraviolet imaging layer via flood exposure of contact mask layer (EUV CML)

(76) Inventors: Robert Bristol, Portland, OR (US); Heidi Cao, Portland, OR (US); Robert Meagley, Hillsboro, OR (US); Bryan Rice, Hillsboro, OR (US); Curtis Ward, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/609,926

(22) Filed: Jun. 30, 2003

(51) Int. Cl. G03F 7/00

(52) U.S. Cl. 430/313; 430/15; 430/316; 430/394

(57) ABSTRACT

A method of forming a device feature using an extreme ultraviolet (EUV) imaging layer (or a sub-deep ultraviolet imaging layer) and one or more other masks layers. The method includes forming a device feature layer; forming a photoresist layer over the device feature layer; forming a contact mask layer (CML) over the photoresist layer; forming an extreme ultraviolet (EUV) imaging layer over the CML; forming a first opening through the EUV imaging layer to expose a first underlying region of the CML; forming a second opening through the CML to expose a second underlying region of the photoresist layer, wherein the second opening is situated directly below the first opening; forming a third opening through the photoresist layer to expose a third underlying region of the device feature layer, wherein the third opening is situated directly below the second opening; forming a fourth opening through the device feature material layer, wherein the fourth opening is situated directly below the third opening.

### FIELD

This disclosure relates generally to semiconductor processing, and in particular, to a method of transferring a pattern formed on an extreme ultraviolet (EUV) imaging layer by way of a flood exposure of a contact mask layer (CML).

### BACKGROUND

The semiconductor industry continually reduces the size of the smallest transistor features in order to increase transistor density and to improve transistor performance. This requirement has driven a concomitant reduction in the wavelength of light used in photolithographic techniques to define these features in photoresist. Extreme Ultraviolet lithography (EUVL) is one such advanced technique, using a wavelength of approximately 11-15 nanometers (nm).

Because of the relatively short wavelength, EUV photoresist can be exposed to define relatively small features. This can be done using an EUV exposure tool comprised of an EUV source, a number of reflective EUV optics (or mirrors), and a stage for holding a (resist-coated) silicon wafer. However, one drawback of EUV lithography is that due to the relatively poor reflectivity of EUV mirrors (approximately 67%), relatively little light reaches the wafer surface. This requires relatively long exposure times, limiting the throughput of an EUVL tool.

Since organic photoresist materials are, in general, highly absorptive to EUV, the exposure dose will be a function of the photoresist thickness. The use of an ultra thin photoresist imaging layer will decrease the required patterning dose.

Another advantage of thin photoresist films is that the side wall angle, which is a function of the resist absorbance, can be improved by the use of ultra thin photoresist imaging layer.

In addition, photoresist collapse is becoming a significant problem as the dimensions of the targets dimensions continue to shrink, because the capillary forces that cause collapse are inversely proportional to the spacing between photoresist structures. The use of ultra thin film imaging will reduce the problem of photoresist collapse.

However, an ultra thin layer of photoresist may not act as an effective mask to enable the patterned etching of the substrate. But this may be solved by transferring the lithographic pattern to a thicker underlying photoresist.

### BRIEF DESCRIPTION OF THE DRAWINGS

FIGS. 1A-F illustrates a side cross-sectional view of a semiconductor device at various stages of a method of forming a device feature in accordance with an embodiment of the invention; and

FIGS. 2A-F illustrates a side cross-sectional view of a semiconductor device at various stages of another method of forming a device feature in accordance with another embodiment of the invention.

### DETAILED DESCRIPTION

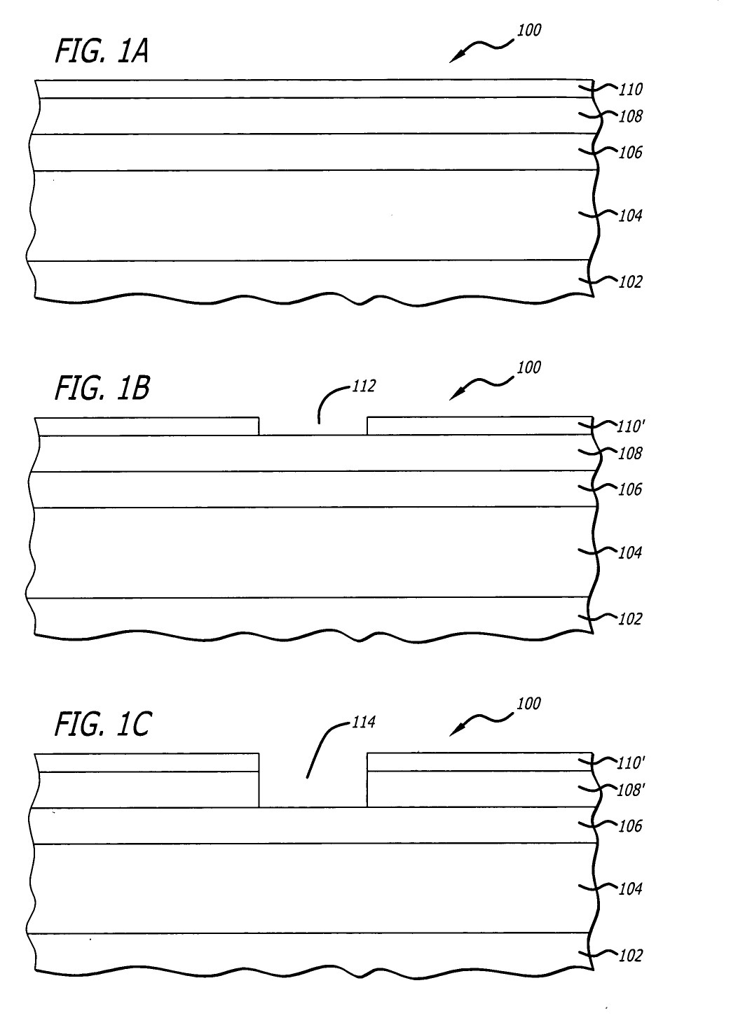

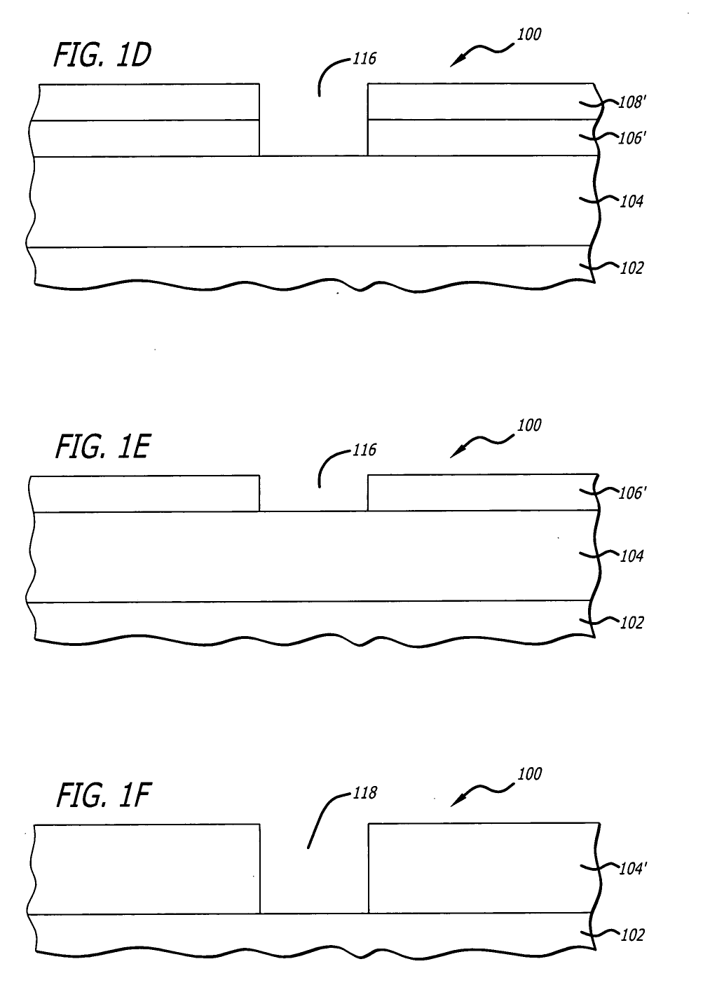

FIG. 1A illustrates a side cross-sectional view of a semiconductor device 100 at a stage of a method of forming a device feature in accordance with an embodiment of the invention. The semiconductor device 100 comprises a substrate 102, a device feature layer 104 deposited over the substrate 102, a photoresist layer 106 deposited over the device feature layer 104, a contact mask layer (CML) 108 deposited over the photoresist layer 106, and an extreme ultraviolet (EUV) imaging layer 110 deposited over the CML 108.

The substrate 102 could be made of any substrate material which needs to be pattered as part of the manufacturing process, such as a silicon, silicon dioxide, silicon-germanium, gallium-arsenide (GaAS), indium-phosphide (InP), etc. The device feature layer 104 could be used to form any device feature such as a gate structure, emitter structure, base structure, an isolation structure, a spacer, a contact, etc. The photoresist layer 106 is a spun-on material that can be exposed with a relatively inexpensive deep ultraviolet (DUV) radiation (e.g. ˜248 nm wavelength) exposure tool or other non-DUV radiation exposure tool.

The CML 108 should be such that the etching thereof should be substantially selective to that of the EUV imaging layer 110. Depending on the relative thickness of the layers, the etch selectivity between the CML 108 and the EUV imaging layer 110 would be approximately greater than a factor of two (2). The CML 108 may be comprised of a spun-on organic material having a DUV reflective/absorptive coating, and having a thickness of approximately ½ wavelength of the exposing radiation (e.g. ˜100 nm). The CML 108 may also have an extinction coefficient (k) of approximately two (2) or greater and an index of refraction (n) of approximately 2.5. In such case, the CML 108 would absorb approximately 50 percent of the DUV radiation.

Another example of a suitable CML 108 is a spun-on sacrificial light-absorbing material (SLAM) or the like (e.g. a spun-on glass). As discussed above, depending on the relative thickness of the layers, the etch selectivity between the SLAM CML 108 and the EUV imaging layer 110 would be approximately a factor of two or greater. The SLAM CML 108 may have a thickness of approximately 150 nm with an EUV absorption of approximately 82 percent. Such material, when properly dyed, could absorb a similar amount of DUV radiation. The SLAM CML 108 could be made thinner than 150 nm, which would require a decreased etch selectivity between the CML 108 and the EUV imaging layer 110.

Yet another example of a suitable CML 108 is a relatively thin layer of silicon which would have a desirable DUV reflective/absorptive property. For instance, the silicon CML 108, having an index of refraction (n) of approximately 1.58, an extinction coefficient (k) of approximately 3.60, and a thickness of approximately 10 nm, would have a reflection of approximately 68 percent and an absorption of approximately 84 percent at a wavelength of 248 nm. Depending on the relative thickness of the layers, the etch selectivity between the silicon CML 108 and the EUV imaging layer 110 would be approximately a factor of two or greater.

The EUV imaging layer 110 may have a thickness of approximately 50 nm. In this example, the EUV imaging layer 100 is spun-on over the CML 108. Although an EUV imaging layer 110 is used to illustrate an embodiment of the invention, it shall be understood that other sub-DUV imaging layers may be used in place thereof. Sub-DUV imaging layer means an imaging layer which is responsive for lithography purposes to radiation having a wavelength of about 157 nm or less.

FIG. 1B illustrates a side cross-sectional view of a semiconductor device 100 at a subsequent stage of a method of forming a device feature in accordance with an embodiment of the invention. According to the method, the EUV imaging layer 110 is patterned and developed to form a pattern 112 (e.g. an opening) that exposes an underlying region of the CML 108. In this example, the EUV imaging layer 110 is exposed using an EUV exposure tool which uses an exposure radiation having a wavelength of approximately 13.5 nm. The remaining EUV imaging layer 110′ serves as a mask for the following patterning of the underlying CML 108.

FIG. 1C illustrates a side cross-sectional view of a semiconductor device 100 at a subsequent stage of a method of forming a device feature in accordance with an embodiment of the invention. According to the method, the CML 108 is etched to transfer the pattern of the EUV imaging layer 110′ to the CML 108 (e.g. forming an opening 114 that exposes an underlying region of the photoresist 106). In the case where the CML 108 is an organic material, the etching of the CML 108 may be performed by an oxygen (O₂) based reactive ion etching (RIE). In the case where the CML 108 is a SLAM, spun-on glass, or the like material, the etching of the CML 108 may be performed by etching in a sulfur hexafluoride (SF6) and argon (Ar) environment (other fluorinated chemistries could also be used, e.g. CH₂F₂). In the case where the CML 108 is silicon, the etching of the CML 108 may be performed by suitable etching techniques. In all of these cases as well as other cases, the etching of the CML 108 should be selective with respect to the remaining EUV imaging layer 110′. The remaining CML 108′ serves as a mask for the following flood exposure and development of the photoresist 106.

FIG. 1D illustrates a side cross-sectional view of a semiconductor device 100 at a subsequent stage of a method of forming a device feature in accordance with an embodiment of the invention. According to the method, the remaining EUV imaging layer 110′ is removed. Then, the semiconductor device 100 is subjected to a flood exposure and then the photoresist 106 is developed to transfer the pattern of the CML 108′ to the photoresist 106 (e.g. to form opening 116 that exposes the underlying region of the device feature layer 104). In this example, the exposure of the photoresist 106 may be performed with a relatively inexpensive DUV flood exposure tool (i.e. not requiring the use of imaging optics). In general, the flood exposure wavelength, CML material, and photoresist (106) material would be matched for optimal performance, i.e. the flood exposure does not necessarily need to be done with DUV.

FIG. 1E illustrates a side cross-sectional view of a semiconductor device 100 at a subsequent stage of a method of forming a device feature in accordance with an embodiment of the invention. According to the method, the remaining CML 108′ is removed. Then, the remaining photoresist 106′ is subjected to a thermal cycle, known as a “hard bake,” to harden the material, enabling it to serve as a mask for the final etch of the underlying substrate.

FIG. 1F illustrates a side cross-sectional view of a semiconductor device 100 at a subsequent stage of a method of forming a device feature in accordance with an embodiment of the invention. According to the method, the etching of the device feature layer 104 is performed to form device features 104′ according to the original pattern formed on the EUV imaging layer 110. Following the formation of the device feature 104′, the hardened photoresist 106′ is removed.

The following method of forming a device feature in accordance with another embodiment is a variation of the method previously described. The following method eliminates the use of the CML layer. Accordingly, the EUV imaging layer is deposited over the photoresist. As will be discussed, the photoresist is developed in a manner that the etch selectivity of the photoresist is greater than the EUV imaging layer such that the EUV imaging layer does not sufficiently degrade in the patterning and development of the photoresist.

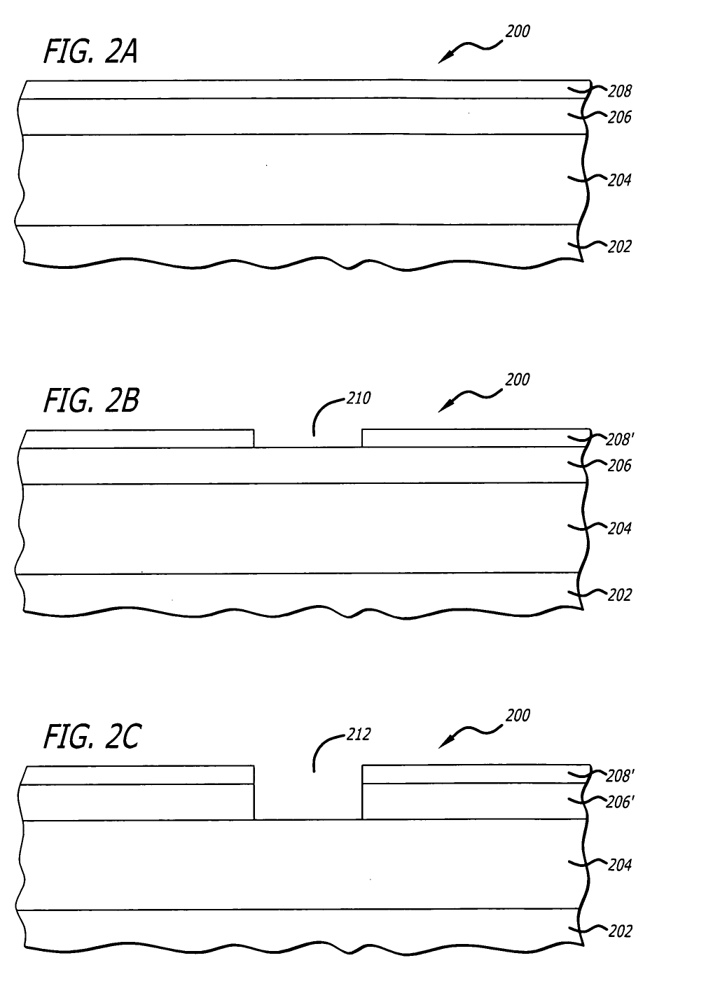

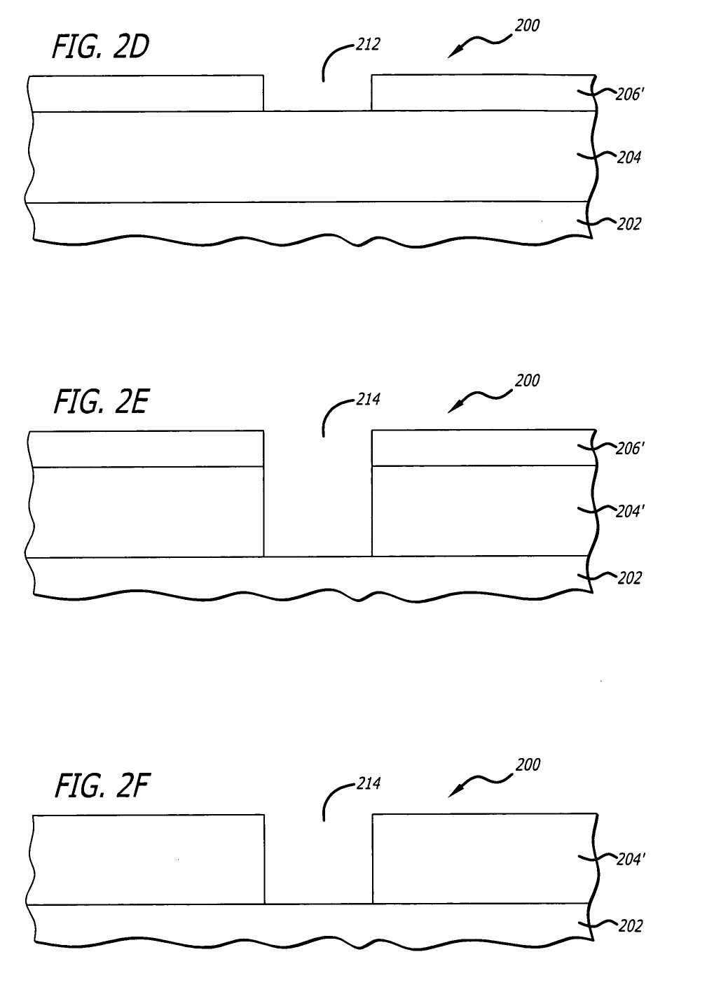

FIG. 2A illustrates a side cross-sectional view of a semiconductor device 100 at a stage of an alternative method of forming a device feature in accordance with another embodiment of the invention. The semiconductor device 200 comprises a substrate 202, a device feature layer 204 deposited over the substrate 202, a photoresist layer 206 deposited over the device feature layer 204, and a extreme ultraviolet (EUV) imaging layer 208 (i.e. a sub-DUV imaging layer) deposited over the photoresist layer 206.

FIG. 2B illustrates a side cross-sectional view of a semiconductor device 200 at a subsequent stage of the alternative method of forming a device feature in accordance with another embodiment of the invention. According to the method, the EUV imaging layer 208 is patterned and developed to form a pattern 210 (e.g. an opening) that exposes an underlying region of the photoresist layer 206. In this example, the EUV imaging layer 208 is exposed using an EUV exposure tool which uses an exposure radiation having a wavelength of approximately 11-15 nm. The remaining EUV imaging layer 208′ serves as a mask for the following patterning and developing of the underlying photoresist layer 206.

FIG. 2C illustrates a side cross-sectional view of a semiconductor device 200 at a subsequent stage of the alternative method of forming a device feature in accordance with another embodiment of the invention. According to the method, the semiconductor device 200 is subjected to a flood exposure and then the photoresist 206 is developed to transfer the pattern of the EUV imaging later 208′ to the photoresist layer 206 (e.g. to form opening 212 that exposes the underlying region of the device feature layer 204). In this example, the exposure of the photoresist 206 may be performed with a relatively inexpensive DUV flood exposure tool (i.e. not requiring the use of imaging optics) or with a non-DUV flood exposure tool. The developing of the photoresist 206 is performed in a manner that does not substantially degrade the remaining EUV imaging layer 208′.

FIG. 2D illustrates a side cross-sectional view of a semiconductor device 200 at a subsequent stage of the method of forming a device feature in accordance with an embodiment of the invention. According to the method, the remaining EUV imaging layer 208′ is removed. Then, the remaining photoresist 208′ is subjected to a hard bake.

FIG. 2E illustrates a side cross-sectional view of a semiconductor device 200 at a subsequent stage of the alternative method of forming a device feature in accordance with an embodiment of the invention. According to the method, the etching of the device feature layer 204 is performed to form device features 204′ according to the original pattern formed on the EUV Imaging later 208. Following the formation of the device feature 104′, the hardened photoresist 206′ is removed as shown in FIG. 2F.

In the foregoing specification, the disclosure has been described with reference to specific embodiments thereof. It will, however, be evident that various modifications and changes may be made thereto without departing from the broader spirit and scope of the embodiments of the invention. The specification and drawings are, accordingly, to be regarded in an illustrative rather than a restrictive sense.

1. A method comprising:
forming a device feature layer;
forming a photoresist layer over said device feature layer;
forming a contact mask layer (CML) over said photoresist layer;
forming a first opening to expose a first underlying region of said contact mask layer;
forming a second opening through said contact mask layer to expose a second underlying region of said photoresist layer, wherein said second opening is situated directly below said first opening;
forming a third opening through said photoresist layer to expose a third underlying region of said device feature layer, wherein said third opening is situated directly below said second opening; and
forming a fourth opening through said device feature material layer, wherein said
fourth opening is situated directly below said third opening.

2. The method of claim 1, wherein forming said second opening through said CML comprises performing an etch process that is selective to said CML.

3. The method of claim 2, wherein an etch selectivity of said contact mask layer is approximately greater than a factor of two.

4. The method of claim 1, wherein said CML comprises an organic material.

5. The method of claim 4, wherein a thickness of said organic CML material is approximately 100 nanometers.

6. The method of claim 4, wherein the extinction coefficient of said organic CML material is approximately 2.

7. The method of claim 4, wherein the index of refraction of said organic CML material is approximately 2.5.

8. The method of claim 4, wherein an absorption of said organic CML material is greater than approximately 50 percent.

9. The method of claim 4, wherein forming second opening through said CML comprises performing an oxygen-based reactive ion etching (RIB) of said CML.

10. The method of claim 1, wherein said CML comprises a sacrificial light absorption material (SLAM).

11. The method of claim 10, wherein an absorption of of said SLAM CML material is greater than approximately 50 percent.

12. The method of claim 10, wherein forming second opening through said CML comprises using a plasma to etch said CML.

13. The method of claim 12, wherein forming second opening through said CML comprises using plasma incorporating sulfur hexafluoride (SF6) and/or argon (Ar) or other fluorinated chemistries, e.g. CH₂F₂ to etch said CML.

14. The method of claim 1, wherein said CML comprises silicon.

15. The method of claim 13, wherein a thickness of said silicon CML material is approximately 10 nanometers.

16. The method of claim 13, wherein an extinction coefficient of said silicon CML material is approximately 3.6.

17. The method of claim 13, wherein a refractive index of refraction of said silicon CML material is approximately 1.58.

18. The method of claim 13, wherein an absorption of said silicon CML material is greater than approximately 50 percent.

19. The method of claim 13, wherein forming second opening through said CML comprises performing an etching of said CML.

20. The method of claim 1, wherein forming said third opening through said photoresist layer comprises performing a flood exposure of said photoresist layer.

21. The method of claim 19, wherein said flood exposure of said photoresist layer uses deep ultraviolet (DUV) radiation.

22. The method of claim 19, wherein said flood exposure of said photoresist uses non-deep ultraviolet (non-DUV) radiation.

23. The method of claim 1, wherein said sub-DUV imaging layer comprises an extreme ultraviolet (EUV) imaging layer.

24. A composition, comprising:
a photoresist layer;
a contact mask layer (CML) situated over said photoresist layer; and
a sub-deep ultraviolet (DUV) imaging layer situated over said CML.

25. The composition of claim 23, wherein said CML comprises an organic material.

26. The composition of claim 23, wherein said CML comprises a sacrificial light absorbing material (SLAM).

27. The composition of claim 23, wherein said CML comprises a spun-on glass.

28. The composition of claim 23, wherein said CML comprises silicon.

29. The composition of claim 23, wherein said sub-DUV imaging layer comprises an extreme ultraviolet (EUV) imaging layer.

30. A method comprising:
forming a device feature layer;
forming a photoresist layer over said device feature layer;
forming a first opening to expose a first underlying region of said photoresist layer;
forming a second opening through said photoresist layer to expose a second underlying region of said device feature layer, wherein said second opening is situated directly below said first opening; and
forming a third opening through said device feature material layer, wherein said third opening is situated directly below said second opening.

31. The method of claim 43 wherein said sub-DUV imaging layer acts as a mask during said forming of said second opening through said photoresist layer.

32. The method of claim 30, wherein forming said second opening through said photoresist layer comprises performing a flood exposure of said photoresist layer.

33. The method of claim 32, wherein said flood exposure of said photoresist layer uses DUV radiation.

34. The method of claim 32, wherein said flood exposure of said photoresist layer uses a non-DUV radiation.

35. The method of claim 43, wherein said sub-DUV imaging layer comprises an extreme ultraviolet (EUV) imaging layer.

36. A composition, comprising:
a device feature layer;
a photoresist layer deposited over said device feature layer; and
a sub-deep ultraviolet (DUV) imaging layer deposited over said photoresist layer.

37 The composition of claim 35, wherein said sub-DIN imaging layer is patterned to serve as a mask for exposing and developing said photoresist layer.

38. The composition of claim 35, wherein an etch selectivity of said photoresist layer is greater than an etch selectivity of said sub-DIN imaging layer.

39. The composition of claim 35, wherein said sub-DUV imaging layer comprises an extreme ultraviolet (EUV) imaging layer.

40. The method of claim 1, further comprising:
forming a DIN imaging layer over said contact mask layer.

41. The method of claim 40, wherein forming said first opening comprises:
forming said first opening through said sub-DUV imaging layer.

42. The method of claim 2, wherein said etch process is selective to said CML with respect to said sub-DUV imaging layer.

43. The method of claim 30, further comprising:
forming a DIN image layer over said photoresist layer.

44. The method of claim 43, wherein forming said first opening comprises:
forming said first opening through said sub-DIN imaging layer.
